(19) United States
(12) Patent Application Publication
(10) Pub. No.: US 2009/0190432 A1
(43) Pub. Date: Jul. 30, 2009

(54) DRAM with Page Access

(76) Inventors: Christoph BILGER, Munich (DE); Peter GREGORIUS, Munich (DE); Michael BRUENNERT, Munich (DE); Maurizio SKERJI, Munich (DE); Wolfgang WALTHES, Munich (DE); Johannes STECKER, Munich (DE); Hermann RUCKERBAUER, Moos (DE); Dirk SCHEIDELER, Munich (DE); Roland BARTH, Munich (DE)

Correspondence Address: SLATER & MATSIL, L.L.P., 17950 PRESTON ROAD, SUITE 1000, DALLAS, TX, 75252, US

(21) Appl. No.: 12/021,109

(22) Filed: Jan. 28, 2008

(51) Int. Cl. G11C 8/12; G11C 8/10

(52) U.S. Cl. 365/238.5; 365/230.06

(57) ABSTRACT

A DRAM chip with a data I/O-interface of an access width equal to a page size.

### TECHNICAL FIELD

Embodiments of the present invention are in the field of dynamic random access memory as, for example, used for data memory for processors.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows an embodiment of a DRAM chip;

FIG. 2 shows a command scheme of an embodiment; and

FIG. 3 shows a flowchart of an embodiment.

### DETAILED DESCRIPTION OF ILLUSTRATIVE EMBODIMENTS

Among the below described Embodiments, some embodiments comprise a DRAM-chip (DRAM=Dynamic Random Access Memory) with a data I/O-interface (I/O=Input/Output) of an access width equal to a page size. A page size may, for example, be determined as the number of bits which are activated by a row command. According to embodiments described below, the page size may be identical to a prefetch size. The prefetch size equals the number of bits accessed with one read or write command. In other words, the prefetch size equals the I/O-width times the burst length of the DRAM.

According to some of the following embodiments, a row command includes the information as to whether a read or write access is desired while the provision of a separate second or column command (including column address) is omitted. Rather, according to embodiments described below, there are no column locations to be selected by column addresses. According to the latter embodiments, all of the columns of a given word line may be used for an access operation. After activation of a word line and sensing of corresponding memory cells, the DRAM may automatically and in a self-timed manner start a read or write operation.

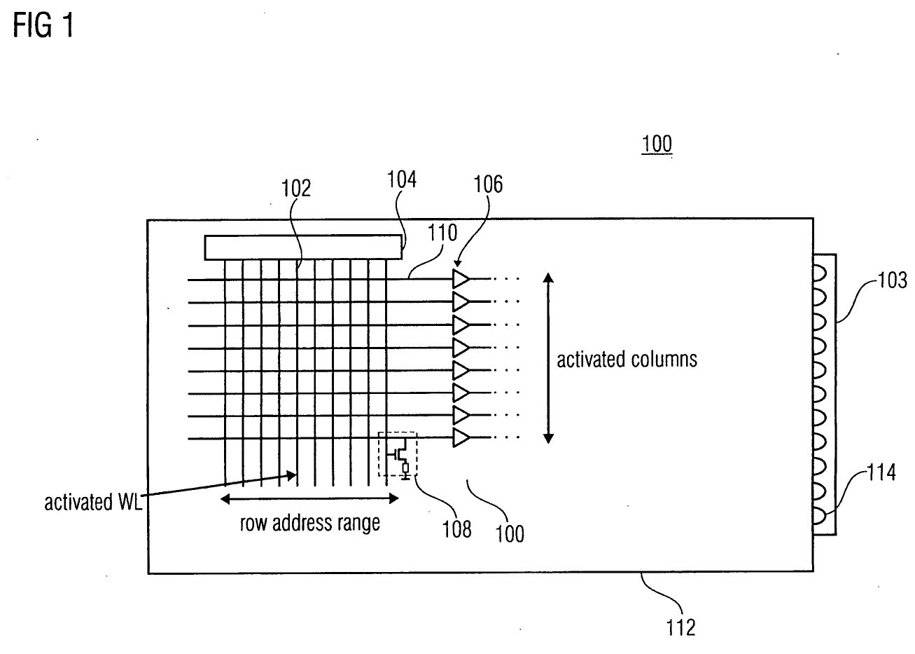

FIG. 1 shows an embodiment of a DRAM chip 100. The DRAM chip 100 has a row address range which is indicated by the double-sided arrow at the bottom of the DRAM chip 100. However, the DRAM chip of FIG. 1 does not have any column address range. Rather, all columns are activated and operated on upon a row address, which is indicated by the vertical double-sided arrow in FIG. 1 labeled “activated columns”.

Each row address activates one individual word line, as exemplarily indicated by the arrow pointing from the left to the right in FIG. 1. Naturally, although FIG. 1 shows merely 10 rows 102 with merely one of these being provided with a reference sign 102, DRAM chip 100 may comprise any number of word lines.

According to an embodiment, the DRAM chip 100 can have a reduced page size and an increased prefetch size relative to a DRAM chip using column addressing, so as to yield a page size equal to the prefetch size, and so that no column selection can be carried out in the DRAM chip 100. The I/O interface of the DRAM chip 100 via which the data accessed by one read or write command leave or enter the chip 100, is indicated by 103.

The DRAM chip 100 may comprise a memory organized in rows, the rows being addressable by row addresses. Moreover, the DRAM chip 100 may comprise a row address decoder 104 being responsive to a row address to activate an associated row, and sense amplifiers 106 being assigned or connectable to the associated rows, so as to sense data of a page size upon activation of the row currently indicated by the row address. In particular, each word line 102 may be connected to several memory cells 108 so as to connect them to a respective bit line 110 upon the word line being activated by a respective row address. The bit lines, in turn, may be connectable to sense amplifiers 106.

Further, the DRAM chip 100 may comprise memory organized in rows, wherein a row size equals a page size. Furthermore, the memory may comprise memory cells 108 and each row address may activate a number of memory cells 108 equal to the page size. In other embodiments, the DRAM chip 100 may further comprise an I/O interface 103 being adapted for receiving a combined activation and read command or a combined activation and write command so that the information as to whether a read or a write is to be processed by the DRAM chip 100 is provided to the DRAM chip along with the activation command.

In embodiments, a DRAM chip 100 may be implemented in a housing 112, wherein the housing 112 may comprise as many pins 114 as bits in a page of binary data. The DRAM chip 100 may even comprise more than this number of pins such as a chip selection pin. The DRAM chip 100 can be adapted for providing data on the I/O-interface or for storing data from the I/O-interface based on a combined activation and read command or a combined activation and write command and a row address.

Embodiments may enable usage with a reduction of the required command bandwidth due to the combined commands. Moreover, embodiments may enable a reduced power consumption due to elimination of column address and associated decoding paths, coming along with reduced latency due to the elimination of margins possibly required for safe timing of consecutive column operations. Moreover, embodiments may enable to be used as third level cache combined with first and second level cache comprising SRAMs.

Embodiments may utilize a prefetch size, which is sufficiently large, i.e., which equals a page size. The page size may be between 64 bytes and 1K bytes.

Embodiments which are for use of a DRAM as a third level cache can utilize a prefetch size, for example, of at least in the range of 64 bytes to 1K bytes.

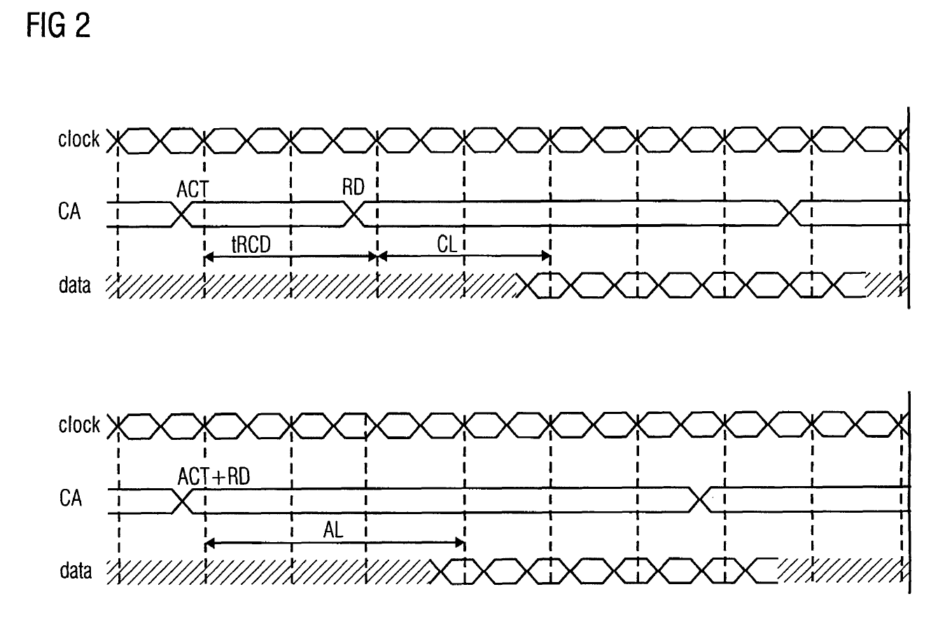

FIG. 2 shows two command schemes for random read accesses. At the top, FIG. 2 shows a command access scheme for a comparison DRAM chip having column addressability. At the bottom, a command scheme for a random read access according to one embodiment is shown. Both schemes show an exemplary clock signal at the top, an exemplary command and address (CA) signal in the middle and an exemplary data signal at the bottom.

With respect to the conventional command scheme, it can be seen at the top of FIG. 2 that the clock signal provides repetitive pulses. Within the command and address (CA) signal, at some point, an activation signal (ACT) is received. A predetermined time tRCD (tRCD=Row address strobe to Column address strobe Delay) after this ACT signal, data can be sensed from the desired row address cells by the sense amplifiers, respectively after tRCD sensing has basically proceeded to a level at which access to the bit line has reached a sufficient certainty. In the example depicted at the top of FIG. 2, a read signal (RD) is received within the CA signal after expiration of tRCD, indicating that data should be read from the DRAM. After receipt of the read signal, a column address strobe latency (CL) has to pass until data can be finally read as indicated in the command scheme at the top of FIG. 2.

At the bottom of FIG. 2, a DRAM command scheme for an embodiment is shown. The clock signal is similar to the one discussed above. From the command and address (CA) signal can be seen that a combined activation and read command (ACT+RD) is received at the same time as the activation signal has been received above. Since no column addresses are present anymore, only a row address strobe delay occurs, which is indicated at the bottom of FIG. 2 by an access latency (AL). After the access latency, data is read from the DRAM. FIG. 2 clearly indicates that embodiments may enable that data may be read earlier since no column address strobe occurs.

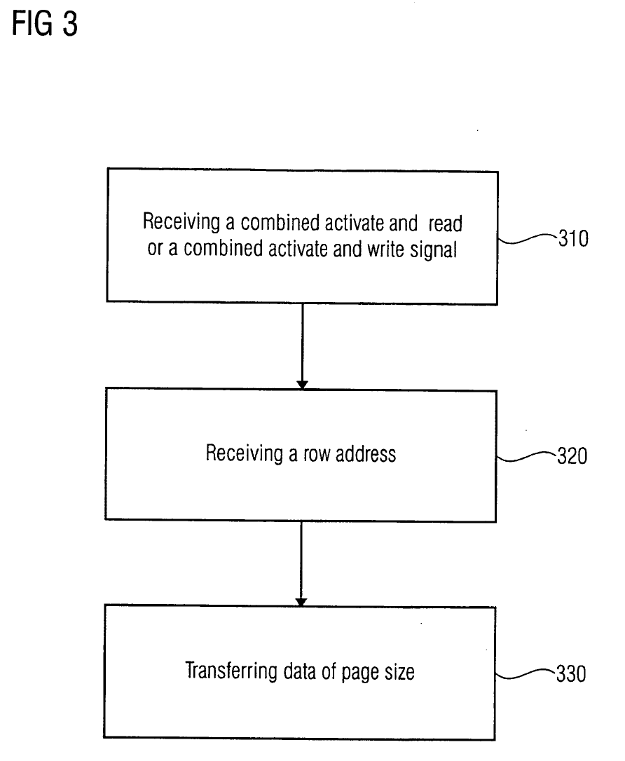

FIG. 3 shows a flowchart of an embodiment of a method for accessing data from a DRAM. FIG. 3 shows a step 310 of receiving a combined activate and read or a combined activate and write signal. Step 310 is followed by step 320 of receiving a row address. In embodiments, combined activate, read and row address or a combined activate, write and row address signal can be received at the same time. Thus, step 310 may precede step 320 logically and in some embodiments also time wise. Subsequently, in step 330, data of a page size is transferred from or to a memory associated with the row address via an I/O-interface, the I/O interface comprising an access width equal to a page size.

Embodiments may enable applications requiring access to a relatively high number of bits at a time as, for example, 1K bits, where conventional DRAM may not be the best compromise anymore. Embodiments may enable usage of DRAM as third level cache for CPUs (CPU=Central Processing Unit), where the embodiments may provide a wide interface with low latency and without multiplexing of row and column addresses.

Embodiments may provide easy access. That is, execution of consecutive commands for read and write accesses may not be necessary. Embodiments may utilize a row command combined with an activate and read or an activate and write command including transfer of row addresses without having the necessity for a column address. Embodiments may, therefore, save valuable command bandwidth, as only row addresses are utilized. Moreover, embodiments may be more robust for different PVT (PVT=Process Voltage Temperature) conditions, as no safe timing is required between row and column addresses.

Depending on certain implementation requirements of the inventive methods, the methods presented above can be implemented in hardware or in software. The implementation can be performed using a digital storage medium, for example, a disc, DVD or CD having electronically stored control signals stored thereon, which incorporate with the programmable computer system such that the inventive methods are performed. Generally, the methods presented above may, therefore, be implemented as a computer program product having a program code stored on a machine-readable carrier, the program code being operative for performing the respective methods when the computer program product runs on a computer. In other words, the above methods may be implemented as a computer program having a program code for performing at least one of the respective methods when the computer program runs on a computer.

While the above invention has been described in terms of several preferred embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

What is claimed is:

1. A DRAM chip with a data I/O-interface of an access width equal to a page size.

2. The DRAM chip of claim 1 with:
a memory organized in rows, the rows being addressable by row addresses;
a row address decoder being responsive to a row address to activate an associated row; and
sense amplifiers being assigned to the associated rows so as to sense data of the page size upon activation of the row.

3. The DRAM chip of claim 1, further comprising an interface being adapted for receiving a combined activation and read command or a combined activation and write command.

4. The DRAM chip of claim 1, wherein the DRAM chip is packaged in a housing, the housing comprising at least as many pins as bits in a page of binary data.

5. The DRAM chip of claim 1, wherein the DRAM chip provides data on the I/O-interface based on a combined activation and read command and a row address.

6. The DRAM chip of claim 1, wherein the DRAM chip stores data from the I/O-interface based on a combined activation and write command and a row address.

7. The DRAM chip of claim 6, wherein the DRAM chip stores data from the I/O-interface based only on a combined activation and write command and a row address.

8. A method for accessing data from a DRAM, the method comprising:
receiving a combined activate and read or a combined activate and write signal;
receiving a row address; and
transferring data of a page from or to a memory associated with the row address via an I/O-interface, the I/O-interface comprising an access width equal to a page size.

9. The method of claim 8, wherein the receiving and the transferring are carried out periodically.

10. The method of claim 8, wherein the transferring is performed without receipt of any column address.

11. A computer program having a program code for performing, when the computer program code runs on a computer, the steps of:
receiving a combined activate and read or a combined activate and write signal;
receiving a row address; and
transferring data of a page size from or to a memory associated with the row address via an I/O-interface, the I/O-interface comprising an access width equal to a page size.

12. The computer program of claim 11, wherein the receiving, the transferring data from the memory and the transferring data to the memory are carried out periodically.

13. A memory device comprising:
a memory including a plurality of dynamic random access memory cells arranged in an array of rows and columns, the memory storing binary data;
an address decoder for receiving a combined activate and read signal or a combined activate and write signal and for receiving a row address associated with one of the rows; and
an I/O interface for transferring data of a page size from or to a memory, the data being associated with the row address, the I/O-interface comprising an access width equal to a page size.

14. The memory device of claim 13, wherein the memory, the address decoder and the I/O interface are all formed in a single semiconductor substrate, the memory device further comprising a plurality of external contacts coupled to the I/O interface for electrically coupling the single semiconductor substrate to circuitry outside of the single semiconductor substrate.

15. The memory device of claim 14, wherein the combined activate and read signal, the combined activate and write signal, and the row address are received through the external contacts.

16. The memory device of claim 15, wherein the I/O-interface includes a number of I/O lines that is greater than or equal to the page size, each of the I/O lines being coupled to an associated one of the external contacts.

17. The memory device of claim 16, wherein the number of I/O lines is between 64 and 1024.

18. The memory device of claim 16, wherein the number of I/O lines is greater than 1000.

19. The memory device of claim 13, wherein the memory device comprises a cache for a central processing unit.

20. The memory device of claim 19, in combination with the central processing unit, wherein the I/O-interface is electrically coupled with I/O lines of the central processing unit.
